(19) United States
(12) Patent Application Publication
(10) Pub. No.: US 2006/0237754 A1
(43) Pub. Date: Oct. 26, 2006

(54) Semiconductor device and method of manufacturing the same

(75) Inventor: Katsuhiro Ishida, Yokkaichi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/408,016

(22) Filed: Apr. 21, 2006

(30) Foreign Application Priority Data
Apr. 22, 2005 (JP) 2005-125191

(51) Int. Cl. H01L 29/76

(52) U.S. Cl. 257/288

(57) ABSTRACT

A semiconductor device includes a semiconductor substrate having a plurality of trenches, a plurality of element isolation regions formed by burying an element isolation insulating film in the trenches, a gate insulating film formed in an element formation region defined between the element isolation regions on the semiconductor substrate, and a gate electrode including a lower gate part which is formed on the gate insulating film in the element formation region and has a side interposed between upper sidewalls of the element isolation region. The gate electrode further includes an upper gate part which is located over the lower gate part and has an underside in contact with the lower gate part. The upper gate part is tapered so that its width is decreased upward from a side end of the underside thereof.

### CROSS-REFERENCE TO RELATED APPLICATIONS

This application is based upon and claims the benefit of priority from the prior Japanese Patent Application No. 2005-125191, filed on Apr. 22, 2005, the entire contents of which are incorporated herein by reference.

### BACKGROUND OF THE INVENTION

1. Field of the Invention

The present invention relates to a semiconductor device provided with a transistor including a gate electrode formed between element isolation regions and a method of manufacturing the same.

2. Description of the Related Art

Semiconductor devices such as NAND flash memories (nonvolatile memories) includes a plurality of memory cells each of which is formed with a control gate electrode and a floating gate electrode. Each memory cell needs to secure a characteristic of a predetermined coupling ratio. The coupling ratio is an index indicative of memory cell characteristic of a flash memory and depends upon an opposing area between the floating and control gate electrodes. The coupling ratio can be rendered higher as the opposing area between the electrodes is large.

In order to increase the opposing area, U.S. Pat. No. 6,624,464 B2 to Shin et al. discloses a technique of forming a floating gate electrode in to a T-shape. According to the disclosed technique, a floating gate electrode includes a lower part formed between element isolation regions adjacent thereto and an upper part which is tapered and protrudes over the element isolation region. Accordingly, when an interpoly insulating film is formed on the floating gate electrode and a control gate electrode is formed on the interpoly insulating film, an opposing area between the floating and control gate electrodes can be increased, whereby the coupling ratio can be rendered higher.

Thus, for the purpose of increasing the opposing area, the floating gate electrode has conventionally been formed so as to protrude over the element isolation region. With recent reduction in circuit design rules, however, employing the aforementioned structure has become more and more difficult.

### BRIEF SUMMARY OF THE INVENTION

Therefore, an object of the present invention is to provide a semiconductor device which can achieve refinement of elements while obtaining a predetermined coupling ratio.

In one aspect, the present invention provides a semiconductor device comprising a semiconductor substrate having a plurality of trenches formed therein, a plurality of element isolation regions formed by burying an element isolation insulating film in the trenches, a gate insulating film formed in an element formation region defined between the element isolation regions on the semiconductor substrate, and a gate electrode including a lower gate part which is formed on the gate insulating film in the element formation region and has a side interposed between upper sidewalls of the element isolation region, the gate electrode further including an upper gate part which is located over the lower gate part and has an underside in contact with the lower gate part, the upper gate part being tapered so that a width thereof is decreased upward from a side end of the underside thereof.

In another aspect, the invention provides a method of manufacturing a semiconductor device comprising forming a gate insulating film on a semiconductor substrate, forming a gate electrode film on the gate insulating film, forming a plurality of trenches by etching the gate electrode film, the gate insulating film and the semiconductor substrate and forming a gate electrode provided with a tapered part, burying a first element isolation insulating film in each trench and forming a spin-on type second element isolation insulating film on the first element isolation insulating film, the second element isolation insulating film having a better burying characteristic than the first element isolation insulating film, and removing the element isolation insulating film formed on a side of the tapered part of the gate electrode.

### BRIEF DESCRIPTION OF THE DRAWINGS

Other objects, features and advantages of the present invention will become clear upon reviewing the following description of the embodiment with reference to the accompanying drawings, in which:

FIG. 1 is schematic sectional view of a partial memory cell region of a non-volatile memory in accordance with one illustrative example of the present invention;

FIG. 2 is a schematic plan view of the memory cell region;

FIG. 3 is a schematic illustration of a first step of the manufacturing process;

FIG. 4 is a schematic illustration of a second step of the manufacturing process;

FIG. 5 is a schematic illustration of a third step of the manufacturing process;

FIG. 6 is a schematic illustration of a fourth step of the manufacturing process;

FIG. 7 is a schematic illustration of a fifth step of the manufacturing process;

FIG. 8 is a schematic illustration of a sixth step of the manufacturing process;

FIG. 9 is a schematic illustration of a seventh step of the manufacturing process; and

FIG. 10 is a sectional view of a modified form

### DETAILED DESCRIPTION OF THE INVENTION

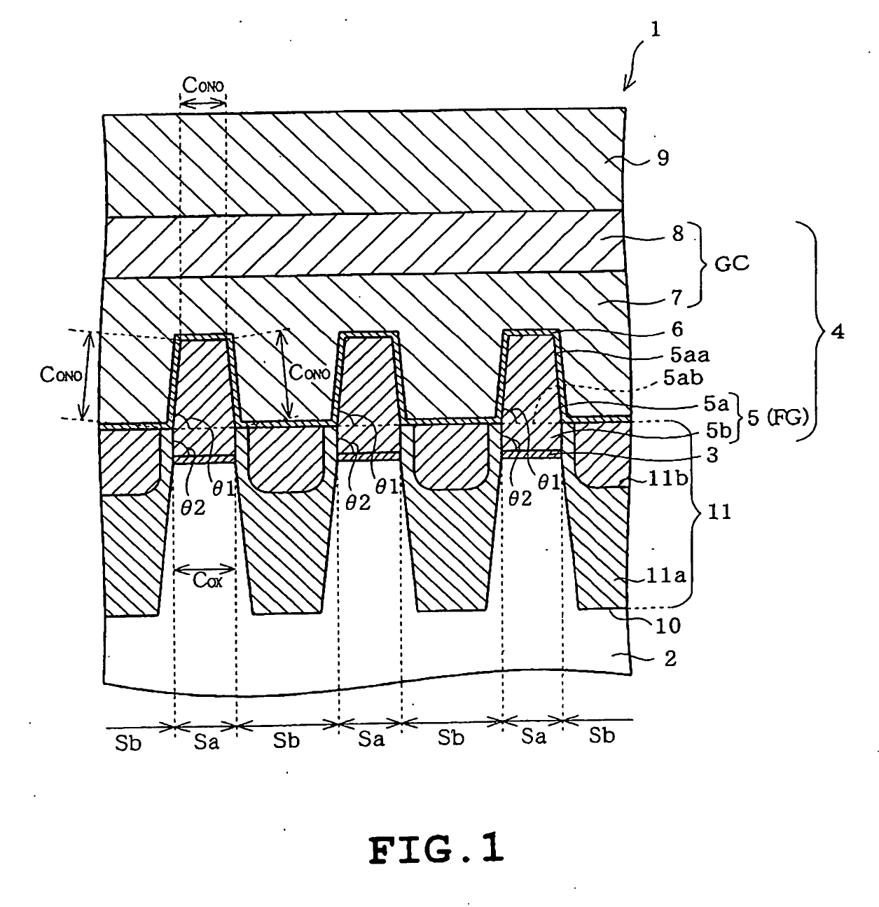

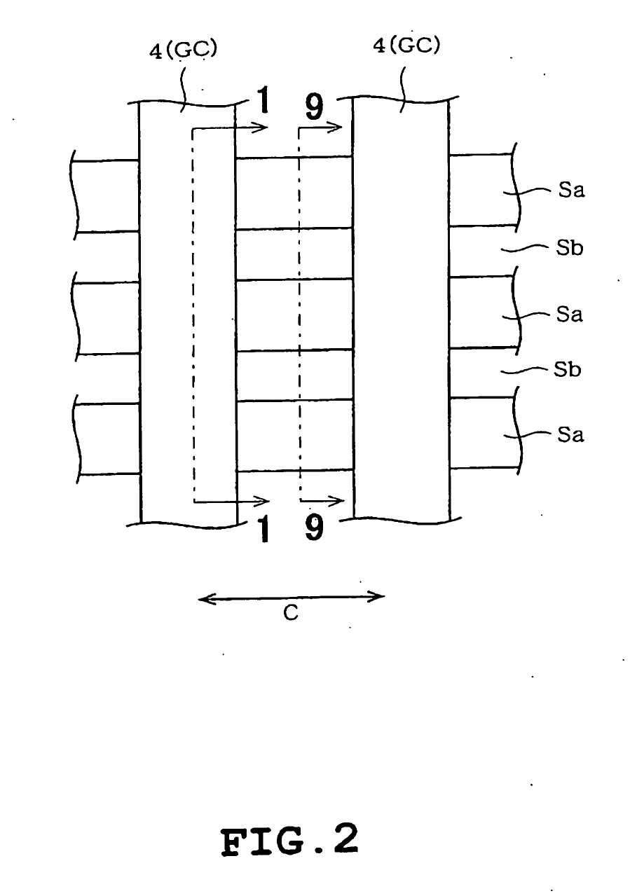

One embodiment of the invention will be described with reference to the accompanying drawings. The invention is applied to a non-volatile memory device such as a flash memory in the embodiment. FIG. 2 schematically shows a partial memory cell region of a non-volatile memory. FIG. 1 is a sectional view taken along line 1-1 in FIG. 2. Reference symbol “GC” in FIG. 2 designates a control gate electrode, reference symbol “FG” designates a floating gate electrode, reference symbol “Sa” designates an element formation region and reference symbol “Sb” designates an element isolation region.

In the following description, the invention is applied to a gate electrode structure in a memory cell region of a non-volatile memory device 1. The invention may be applied to a peripheral circuit region of the non-volatile memory device 1, if possible. In the following description and the present invention, the term, “rectangular” means that a section is rectangular and the term also encompasses the meaning of a term, “square.”

### Gate Electrode Structure in Memory Cell Region

Element formation regions Sa are divided by element isolation regions Sb each of which has a shallow trench isolation (STI) structure as shown in FIG. 1. A gate electrode in the memory cell region is insulated and thereby isolated by the element isolation region Sb.

1. Structure of Element Formation Region Sa

The non-volatile memory device 1 comprises a silicon substrate 2 serving as a semiconductor substrate as shown in FIG. 1. A gate oxide film 3 serving as a gate insulating film is formed on the silicon substrate 2 in the element formation region Sa. The gate oxide film 3 is comprised of a silicon oxide film. A multilayer gate electrode 4 is formed on the gate oxide film 3. The multilayer gate electrode 4 is comprised of a first polycrystalline silicon film 5 serving as a first conductive film, an oxide-nitride-oxide (ONO) film 6 serving as an interpoly insulating film (inter-gate insulating film) and formed so as to be covered with the first polycrystalline silicon film 5, a second polycrystalline silicon film 7 serving as a second conductive film and formed on the ONO film 6 and a tungsten silicide (WSi) film 8 serving as a low resistivity metal film. The first polycrystalline silicon film 5 constitutes a floating electrode FG serving as a gate electrode. The second polycrystalline silicon film 7 and the WSi film 8 constitute a control gate electrode GC.

The first polycrystalline silicon film 5 includes upper and lower parts 5a and 5b serving as upper and lower gate parts respectively. The upper part 5a of the film 5 is tapered upward from a side end of a lowermost side 5ab so that a part thereof located higher than the lowermost side 5ab in contact with the lower part 5b has a smaller width than the lowermost side 5ab. Furthermore, the lower part 5b of the film 5 has a rectangular section. A taper angle θ1 between the upper surface of the silicon substrate 2 and a side of the upper part 5a is set at about 85°, for example. An angle θ2 between the upper surface of the silicon substrate 2 and a side (sidewall surface) of the lower part 5b is set at about 90° and is larger than the taper angle θ1, for example.

The ONO film 6 is formed on the first polycrystalline silicon film 5 so as to cover the latter. The second polycrystalline silicon film 7 is formed on the ONO film 6. The Wsi film 8 is formed on the second polycrystalline silicon film 7. A silicon nitride film 9 is formed on the WSi film 8.

2. Element Isolation Region Sb

Trenches 10 are formed in a plurality of element isolation regions Sb of the silicon substrate 2 respectively. Each trench 10 isolates the corresponding first polycrystalline silicon film 5 in the memory cell region. An element isolation insulating film 11 is buried in each trench 10. For example, a tetraethyle orthosilicate (TEOS) film 11a serving as a first element isolation insulating film is buried in a lower interior of the trench 10. For example, a spin-on type insulating film 11b serving as a second element isolation insulating film is buried in an upper interior of the trench 10 so that a lower part of the insulating film 11b is covered by the TEOS film 11a. The spin-on type insulating film 11b is made from a polysilazane solution which is a silica film-forming application liquid, for example. In the embodiment, the element isolation insulating film 11 has a two-layer structure including TEOS film 11a and a spin-on type insulating film 11b having a better burying characteristic than the TEOS film 11a.

The element isolation insulating film 11 has an upper surface which is located higher than upper surfaces of the gate oxide films 3 formed between adjacent element isolation insulating films 11. More specifically, each element isolation insulating film 11 includes an upper part protruding upward from the upper surface of the silicon substrate 2. The upper surface of each element isolation insulating film 11 corresponds substantially to the lowermost side 5ab of the tapered part 5aa formed on the upper part 5a of the first polycrystalline silicon film 5, as shown in FIG. 1. Furthermore, the upper surface of each element isolation insulating film 11 is adapted to correspond to an interface between the upper and lower parts 5a and 5b of the first polycrystalline silicon film 5. The lower part 5b of the first polycrystalline silicon film 5 is interposed between sidewalls of the adjacent element isolation insulating films 11 protruding upward from the upper surface of the silicon substrate 2.

The ONO film 6 continuous from the element formation region Sa is formed on the element isolation insulating film 11. Furthermore, the control gate electrode GC is located over a plurality of element formation regions Sa and a plurality of element isolation regions Sb.

The coupling ratio is one of indexes of characteristics of a memory cell composing the non-volatile memory device 1. The coupling ratio Cr is expressed as the following equation:
Cr=Cono/(Cono+Cox) (1)

An ideal value of the coupling ratio Cr of equation (1) is 1. The value of Cono indicates a capacity between the first and second polycrystalline silicon films 5 and 7 opposed to each other with the ONO film 6 being interposed therebetween or between the floating gate FG and the control gate electrode GC. The value of Cox indicates a capacity of a capacitor between the silicon substrate 2 and the first polycrystalline silicon film 5 both of which are opposed to each other with the gate oxide film 3 being interposed therebetween. The coupling ratio Cr becomes larger as an opposing area between the first and second polycrystalline silicon films 5 and 7 is increased. On the contrary, the coupling ratio Cr becomes smaller as the opposing are is reduced.

The floating gate FG has conventionally been formed so as to protrude over the upper surface of the element isolation region Sb. The coupling ratio Cr has conventionally been increased by increasing an opposing area between the upper surface of the floating gate electrode FG and the underside of the control gate electrode GC. In the embodiment, however, the height of the floating gate electrode FG is increased so that the opposing area between the sides of the floating gate electrode FG and the control gate electrode GC becomes larger, whereby the coupling ratio Cr is increased, instead of protruding the floating gate electrode FG over the upper surface of the region Sb.

### Manufacturing Process

A method of manufacturing gate electrodes in the memory cell regions of the non-volatile memory device 1 will be described. More specifically, the invention is applied to a method of forming a gate insulating film (gate insulating film) and a gate electrode (gate electrode film) in advance of the forming of the element isolation region Sb.

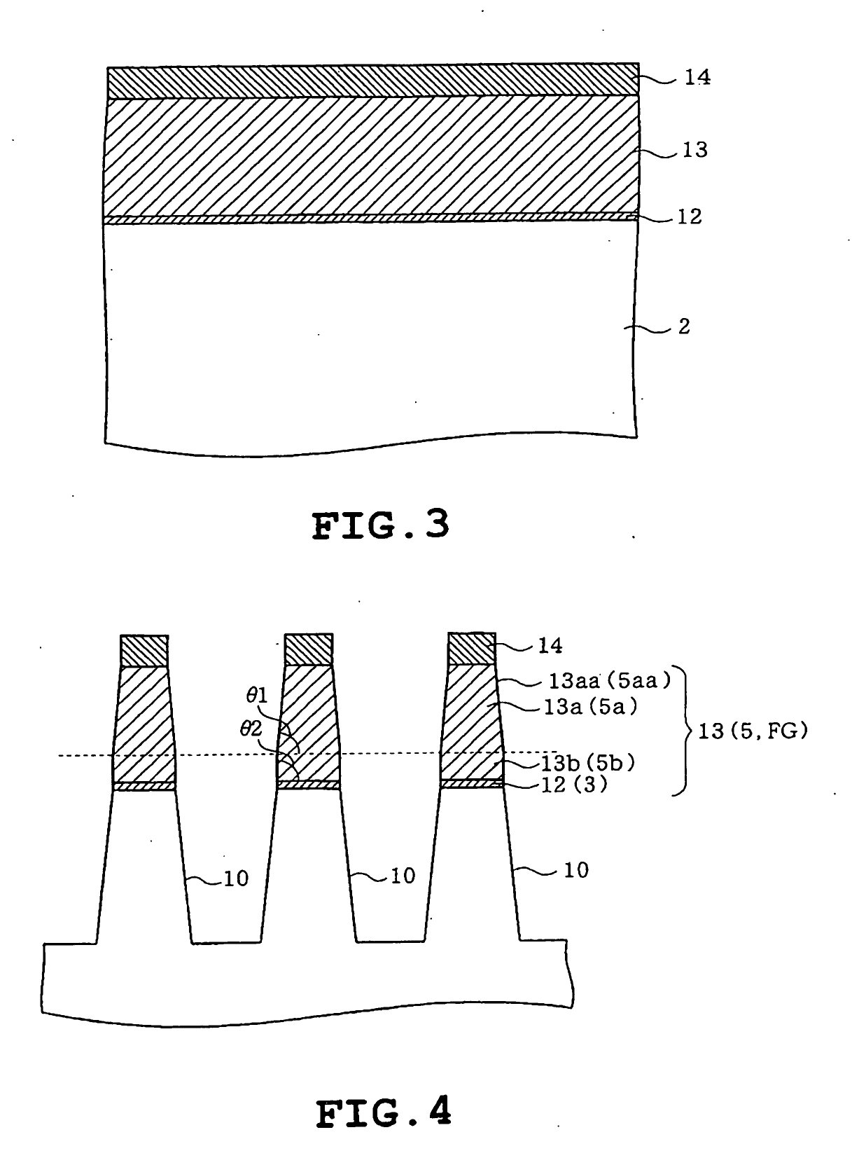

Referring first to FIG. 3, the gate insulating film 12 for formation of a gate insulating film, such as a silicon oxide film, is formed on the silicon substrate 2 so as to have a film thickness of 10 nm, for example. A polycrystalline silicon film 13 serving as a gate electrode film is formed on the gate insulating film 12 so as to have a film thickness of 100 nm, for example. A silicon nitride film 14 with a film thickness of, for example, 50 nm is formed on the polycrystalline silicon film 13. The film thickness of the polycrystalline silicon film 13 is set so that a predetermined coupling ratio is achieved.

Subsequently, as shown in FIG. 4, a resist pattern is formed on the silicon nitride film 4, and the silicon nitride film 14, the polycrystalline silicon film 13, the gate insulating film 12 and the silicon substrate 2 are removed by an anisotropic etching process so that a trench 10 is formed. In a step of forming the trench 10, the etching process is carried out with the conditions being adjusted, whereby the upper part 13a of the polycrystalline silicon film 13 is tapered and the lower part 13b of the film 13 is formed so as to have a rectangular longitudinal section. As described above, the taper angle θ1 of the upper part 13a is set at 85°, whereas the angle θ2 of the lower part 13b is set at 90° and is larger than the angle θ1. The upper part 13a of the polycrystalline silicon film 13 corresponds to the upper part 5a of the polycrystalline silicon film 5 as shown in FIG. 1, whereas the lower part 13b of the film 13 corresponds to the lower part 5b of the film 5 as shown in FIG. 1. The gate insulating film 12 corresponds to the gate oxide film 3.

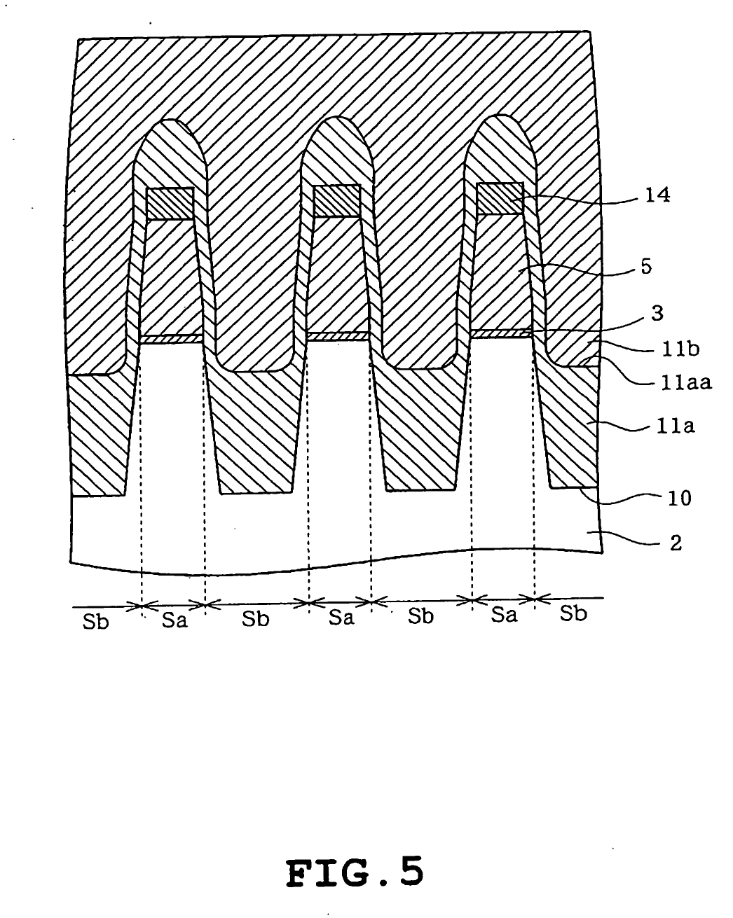

Subsequently, the resist is removed and, as shown in FIG. 5, the TEOS film 11a constituting the element isolation insulating film 11 is formed on an inner surface of the trench 10 in the silicon substrate 2, and the spin-on type insulating film is buried and formed inside the TEOS film 11a in the trench 10. When the width of the element isolation region Sb is reduced and the film thickness of the polycrystalline silicon film 13 is increased so that a predetermined coupling ratio is obtained, an aspect ratio of the trench from the bottom of the trench to the upper surface of the silicon nitride film 14 is increased. When the aspect ratio of the trench is increased, it becomes difficult to bury the TEOS film 11a in the trench completely. Accordingly, in the embodiment, after the TEOS film 11a has been buried midway in the trench 10, the spin-on type insulating film 11b having a better burying characteristic than the TEOS film 11a is then buried. In this case, the TEOS film 11a is buried in the trench 10 so that an upper end face 11aa of the TEOS film 11a is located lower than a forming face of the gate oxide film 3, for example. Since the spin-on type insulating film 11b is buried over the upper end face 11aa of the TEOS film 11a, the spin-on type insulating film 11b is also buried below the forming face of the gate oxide film 3. Subsequently, heat treatment is carried out to such a degree that the silicon substrate 2, the floating gate electrode FG and the like are prevented from oxidation, whereby the spin-on type insulating film 11b is oxidated.

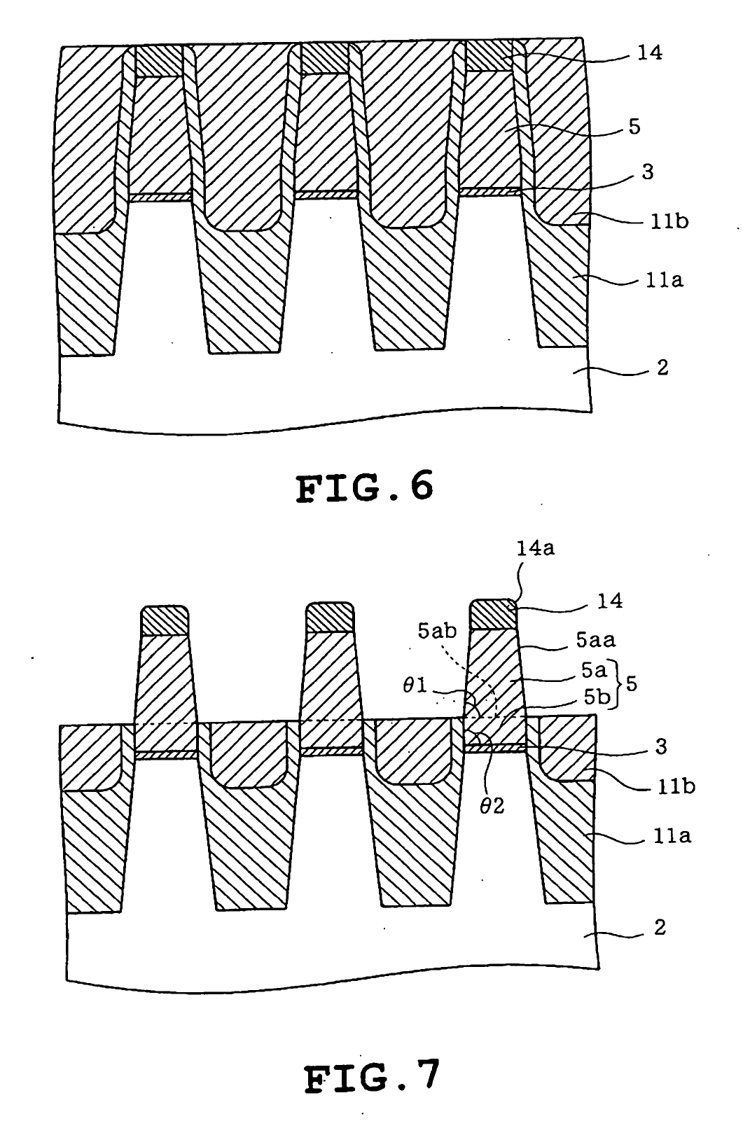

Subsequently, as shown in FIG. 6, the buried TEOS film 11a and spin-on type insulating film 11b are flattened by the CMP process with the silicon nitride film 14 serving as a stopper. Subsequently, as shown in FIG. 7, a dry etching process is carried out for the TEOS film 11a and spin-on type insulating film 11b using, for example, C₄F₈/CO/Ar gas plasma with the silicon nitride film 14 serving as a mask. In this case, the TEOS film 11a and spin-on type insulating film 11b are processed until the upper surfaces of the TEOS film 11a and spin-on type insulating film 11b are on a level with the upper surface of the lower part 5b of the polycrystalline silicon film 5.

When a hitherto used TEOS film formed by the low pressure chemical vapor deposition (LP-CVD) or by the high density plasma (HDP-) CVD is used as the element isolation insulating film, instead of the spin-on type insulating film 11b, both dry etching process and wet etching process are used for removal of buried insulating films. The LP-CVD and HDP-CVD belong to a plasma CVD process. On the other hand, there is a problem that the spin-on type insulating film 11b is peeled off without sufficient heat treatment after application when a wet etching process with use of hydrofluoric acid is carried out. Accordingly, sufficient heat treatment is required for prevention of peeling of the spin-on type insulating film 11b in the non-volatile memory device 1 employing the spin-on type insulating film 11b. However, if sufficient heat should be applied to the spin-on type insulating film 11b, the silicon substrate 1, the floating gate electrode FG and the like would be oxidated. Thus, application of sufficient heat would result in a new problem. In view of the problem, only the dry etching process is carried out for the element isolation insulating film 11 including the spin-on type insulating film 11b without execution of the wet etching process in the embodiment.

In order that only the element isolation insulating film 11 may selectively be removed while etching of the silicon nitride film 14 and the polycrystalline silicon film 5 are suppressed, the processing conditions need to be set so that a higher selection ratio is given to the silicon nitride film 14 and the polycrystalline silicon film 5. However, anisotropy is increased when a higher selection ratio of the silicon nitride film 14 and the polycrystalline silicon film 5 are obtained in the execution of the dry etching process. When the taper angle θ1 is not less than 90°, accumulation of reactive substance on the sidewall of the polycrystalline silicon film progresses in the stage of removal of the element isolation insulating film 11. As a result, the element isolation insulating film located on the sides of the first polycrystalline silicon film 5 is difficult to remove and accordingly, the sidewall of the first polycrystalline silicon film 5 cannot be exposed. Even if the ONO film 6 and the second polycrystalline silicon film 7 should be formed under the aforementioned condition, the capacity of the capacitor corresponding to the side of the first polycrystalline silicon film 5 could not be rendered large.

In the embodiment, as shown in FIG. 7, the upper part 5a of the film 5 is tapered upward from the side end of the lowermost side 5ab so that the taper angle θ1 between the upper surface of the silicon substrate 2 and the side of the upper part 5a is set at about 85°. Thus, when the tapered shape is provided, ion such as CF ion during the dry etching process and the sputtering effect (Ar gas) in the etching process can directly be imparted to the tapered portion 5aa of the upper part 5a of the first polycrystalline silicon film 5, whereupon the TEOS film 11a and the spin-on type insulating film 11b can be removed only by the dry etching process.

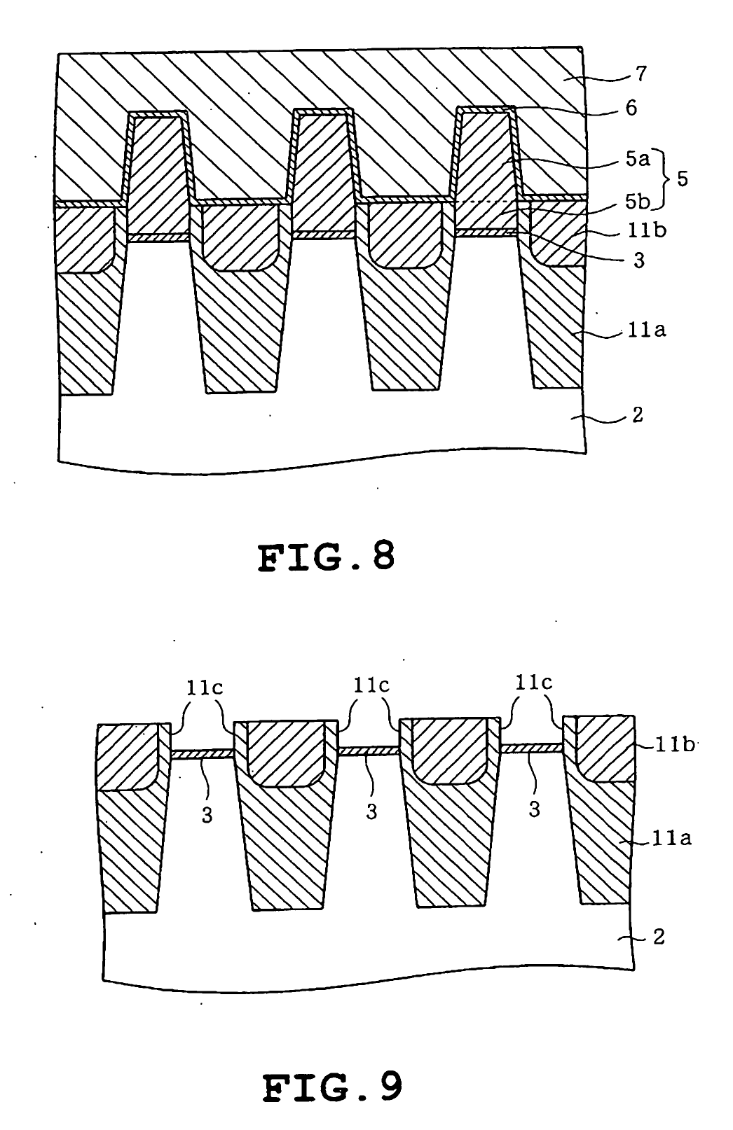

Subsequently, as shown in FIG. 8, the silicon nitride film 14 is removed by the wet etching process, and the ONO film 6 comprising a silicon oxide film/silicon nitride film/silicon oxide film can be formed isotropically on the upper surface and the side of the first polycrystalline silicon film 5. The second polycrystalline silicon film 7 is formed on the ONO film 6. Thereafter, as shown in FIG. 1, the WSi film 8 is formed on the upper part of the second polycrystalline silicon film 7. The silicon nitride film 9 is formed on the WSi film 8. A silicon oxide film may be used instead of the silicon nitride film 9.

Subsequently, adjacent multilayer gate electrodes 4 are insulated and isolated from each other. More specifically, as shown in FIG. 2, a step is carried out in which the multilayer gate electrodes 4 (floating gate electrodes FG; or control gate electrodes GC) are electrically insulated and isolated from each other. FIG. 9 shows a section taken along line 9-9 in FIG. 2 after removal of the film between the multilayer gate electrodes 4 adjacent to each other in the direction of arrow C in FIG. 2. In the insulating and isolating step, resist (not shown) is applied to the silicon nitride film 9 and then patterned. A dry etching process is carried out for the silicon nitride film 9, the tungsten silicide film 8, the second polycrystalline silicon film 7, the ONO film 6 and the first polycrystalline silicon film 5 so that a trench is formed between the adjacent multilayer gate electrodes 4. In this case, since the upper part 5a of the first polycrystalline silicon film 5 has an inclined side, ion such as CF ion during the dry etching process and the sputtering effect (Ar gas) in the etching process can effectively be imparted to the ONO film 6, whereupon the ONO film 6 can be removed easily.

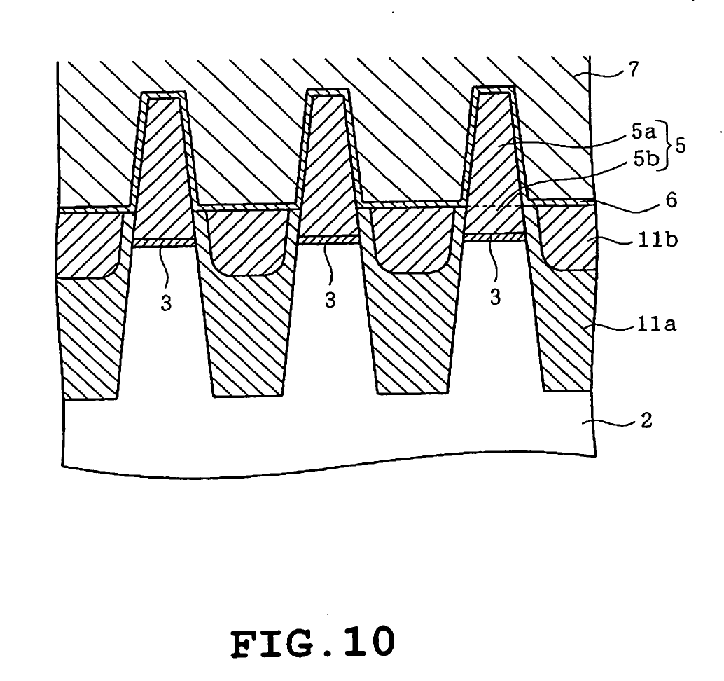

Referring now to FIG. 10, a modified form is shown. When a side of the lower part 5b of the first polycrystalline silicon film 5 is also tapered as well as the upper part 5a thereof, the element isolation insulating film 11 is formed so as to overlap the side of the lower part 5b of the film 5. In order that the adjacent multilayer gate electrodes 4 may be isolated from each other in this state, the films 6 to 9 are removed and thereafter, the first polycrystalline silicon film 5 is removed by the dry etching process. As a result, the film remains on the sidewalls of the element isolation insulating film 11. There is a possibility that the remaining film may connect the first polycrystalline silicon films 5 constituting the floating gate electrodes FG adjacent to each other in the direction of arrow C. This would result in failure of the device.

In view of the aforementioned problem, only the side of the upper part 5a of the first polycrystalline silicon film 5 is inclined, whereas the side of the lower part 5b is formed so as to be perpendicular to the upper surface of the silicon substrate 2. Accordingly, when the element isolation insulating film 11 is formed through the above-described steps, the upper part 11c of the element isolation insulating film 11 also has a side perpendicular to the upper surface of the silicon substrate 2. When the films 5 to 9 between the adjacent multilayer gate electrodes 4 is removed by the dry etching process, first polycrystalline silicon film 5 can be prevented from remaining on the side of the upper part 11c of the element isolation insulating film 11 located over the forming face of the gate oxide film 3. Consequently, occurrence of short circuit can be prevented between the floating gate electrodes FG adjacent to each other in the direction of arrow C in FIG. 2.

Subsequently, an interlayer insulating film (not shown) is deposited, and contact holes are formed through the interlayer insulating film. A metal such as tungsten is buried in the contact holes thereby to be formed into contact plugs (not shown). An upper wiring layer (not shown) is formed on the interlayer insulating film and then connected to the contact plugs. Since the subsequent steps are ordinary, the description of these steps will be eliminated. The non-volatile memory 1 is thus manufactured through the above-described steps.

As obvious from the foregoing, the manufacturing method of the embodiment has the following features. The gate insulating film 12 comprising a silicon oxide film is formed on the silicon substrate 2. The polycrystalline silicon film 13 serving as the gate electrode film is formed on the gate insulating film 12. A plurality of trenches 10 are formed in the films 12 and 13, and the silicon substrate 2. As a result, the first polycrystalline silicon film 5 (floating gate electrode FG) and the gate oxide film 3 are formed. The polycrystalline silicon film 5 includes the lower part 5b with the side perpendicular to the upper surface of the silicon substrate 2. The TEOS film 11a and the spin-on type insulating film 11b are buried in each trench 10. The element isolation insulating film 11 formed on the side of the tapered part 5aa of the upper part 5a of the film 5 is removed.

According to the above-described manufacturing method, the opposing area between the floating gate electrode FG and the control gate GC can be rendered stable even when the aspect ratio is increased with an increase in the film thickness of the polycrystalline silicon film, whereupon a proper coupling ratio can normally be obtained.

The spin-on type insulating film 11b serving as a part of the element isolation insulating film 11 is buried and formed. The element isolation insulating film 11 formed on the tapered part 5aa of the upper part 5a of the film 5 is removed only by the dry etching process. Consequently, the spin-on type insulating film 11b can be prevented from being delaminated with the wet etching proves.

Furthermore, when the films 5 to 9 formed the region between the multilayer gate electrodes 4 adjacent in the direction of arrow C in FIG. 2, the first polycrystalline silicon film 5 formed on the side of the upper part 11c of the element isolation insulating film 11 can be removed substantially without remaining since the side of the upper part 11c located over the forming face of the gate oxide film 3 is perpendicular to the upper surface of the silicon substrate 2. Consequently, occurrence of short circuit can be prevented between the floating gate electrodes FG adjacent to each other in the direction of arrow C in FIG. 2.

The present invention should not be limited to the above-described embodiment but may be modified or expanded as follows. Although the floating gates FG are formed in the memory cell region in the foregoing embodiment, the invention may be applied to an arrangement in which ordinary transistors are formed in a peripheral circuit region, instead. Furthermore, although the upper part 5a of the first polycrystalline silicon film 5 is tapered in the foregoing embodiment, the tapered part 5aa may be formed so as to have a plurality of stepped portions. Furthermore, in case where a transistor is formed by utilizing a process of forming a gate electrode in advance of the element isolation region Sb, a gate electrode of the transistor may be formed into a tapered shape. However, the width of a gate electrode in such an ordinary transistor has been reduced with recent reduction in the electrical circuit design rules. Accordingly, the level of the gate needs to be increased so that the capacity of the gate electrode is increased and high resistivity of the gate electrode needs to be suppressed. In this case, when at least a part of the gate electrode is tapered, the element isolation insulating film 11 formed on a side of the gate electrode can easily be removed. Accordingly, substantially the same effect can be achieved from the modified form as from the foregoing embodiment.

Both TEOS film 11a and spin-on type insulating film 11b are used as the element isolation insulating film 11 in the foregoing embodiment. However, each of conventionally used TEOS film made by the LP-CVD or HDP-CVD process and TEOS-O₃ film may be used as a simple substance. In this case, although the dry etching is carried out for removal of these films in the foregoing embodiment, a wet etching process may be carried out, instead.

The foregoing description and drawings are merely illustrative of the principles of the present invention and are not to be construed in a limiting sense. Various changes and modifications will become apparent to those of ordinary skill in the art. All such changes and modifications are seen to fall within the scope of the invention as defined by the appended claims.

What is claimed is:

1. A semiconductor device comprising:
a semiconductor substrate having a plurality of trenches formed therein;
a plurality of element isolation regions formed by burying an element isolation insulating film in the trenches;
a gate insulating film formed in an element formation region defined between the element isolation regions on the semiconductor substrate; and
a gate electrode including a lower gate part which is formed on the gate insulating film in the element formation region and has a side interposed between upper sidewalls of the element isolation region, the gate electrode further including an upper gate part which is located over the lower gate part and has an underside in contact with the lower gate part, the upper gate part being tapered so that a width thereof is decreased upward from a side end of the underside thereof.

2. The semiconductor device according to claim 1, wherein the semiconductor substrate has a surface and the lower gate part of the gate electrode a side vertical relative to the surface of the semiconductor substrate.

3. The semiconductor device according to claim 1, wherein the element isolation insulating film includes a first element isolation insulating film buried in a lower interior of each trench and a spin-on type second element isolation insulating film provided over the first element isolation insulating film and having a better burying characteristic than the first element isolation insulating film, and the semiconductor substrate has a surface and the element isolation region has an upper part protruding from the surface of the semiconductor substrate.

4. The semiconductor device according to claim 1, wherein the element isolation insulating film includes a first element isolation insulating film buried in a lower interior of each trench and a spin-on type second element isolation insulating film provided over the first element isolation insulating film and having a better burying characteristic than the first element isolation insulating film, and the element isolation region has an upper part protruding from the surface of the semiconductor substrate.

5. A method of manufacturing a semiconductor device comprising:
forming a gate insulating film on a semiconductor substrate;
forming a gate electrode film on the gate insulating film;
forming a plurality of trenches by etching the gate electrode film, the gate insulating film and the semiconductor substrate and forming a gate electrode provided with a tapered part;
burying a first element isolation insulating film in each trench and forming a spin-on type second element isolation insulating film on the first element isolation insulating film, the second element isolation insulating film having a better burying characteristic than the first element isolation insulating film; and
removing the element isolation insulating film formed on a side of the tapered part of the gate electrode.

6. The method according to claim 5, wherein in the step of forming the gate electrode on the tapered part, the gate electrode is formed so that the tapered part is provided on an upper side of the gate electrode, and an upper part of the gate electrode is formed into a rectangular shape.
